(19) United States
(12) Patent Application Publication
(10) Pub. No.: US 2017/0040195 A1
(43) Pub. Date: Feb. 9, 2017

(54) TOOLING FOR A PACKAGE ENCLOSING ELECTRONICS AND METHODS OF USE THEREOF

(71) Applicant: Microcircuit Laboratories LLC, Kennett Square, PA (US)

(72) Inventors: Richard Richardson, Kennett Square, PA (US); James K. Anders, Southampton, PA (US)

(21) Appl. No.: 15/229,782

(22) Filed: Aug. 5, 2016

Related U.S. Application Data
(60) Provisional application No. 62/202,221, filed on Aug. 7, 2015.

(51) Int. Cl. H01L 21/67; H01L 23/02; H01L 21/50; H01L 21/68

(52) U.S. Cl. CPC H01L 21/67126; H01L 21/68; H01L 23/02; H01L 21/50

(57) ABSTRACT

The disclosure relates to a precise cut, reusable tooling assembly used to precisely hold and align a package base during manufacture into an electronic package that protects electronic circuits, microelectronic circuits and semiconductors. The assembly comprises a carrier plate and a template, and an optional interface bloc, all of which secure a lower or intermediate section of the outer periphery of the package base to prevent movement of the package base during manufacturing processes. The assembly can also be used to transfer a sealed electronic package between manufacturing process equipment by hand without having to contact the electronic package. The invention includes end effector tooling useful for precisely aligning a lid relative to a package body. The effector tooling includes an angled surface that contacts upper edges of a lid and seal ring.

### CROSS-REFERENCE TO RELATED APPLICATION

This application claims the priority and benefit of U.S. Provisional Patent Application No. 62/202,221, titled “Tooling for an Electronic Package,” filed on Aug. 7, 2015, which is incorporated by reference herein in its entirety.

### FIELD OF THE INVENTION

The invention relates generally to the field of tooling used to manufacture sealed packages or other containment devices for electronics, semiconductors, or microelectronics. The invention relates specifically to a tooling assembly having at least one precision cut receptacle that contacts an external aspect of a package base and securely supports the package base during static and dynamic movement of the package base relative to manufacturing processes and other handling. The tooling assembly can be used repeatedly to produce packages that are consistently sealed. The tooling assembly can be used to transfer the package base during and after the manufacturing process without having to directly touch or handle the sealed package. The tooling assembly is reusable, and its component parts are interchangeable. The invention includes methods for manufacturing a tooling assembly, as well as methods and systems for using the tooling assembly to produce sealed packages.

### BACKGROUND OF THE INVENTION

Sealed package enclosures contain electronics, microelectronics, precision components, RF packages, semiconductors, circuits, microcircuits, integrated circuits, optoelectronic devices, and/or sensors. A sealed package is designed to encase and protect delicate electronics and connections contained within the sealed package. The sealed package is often hermetically sealed to protect the internal components from moisture, contamination, and corrosion.

A sealed package generally comprises a base with a closed bottom, upstanding side walls having a top surface, and a lid placed over the open top of the base and sealed to the top of the base. Some package bases have side walls that include an added seal ring, while others have a side wall having a top surface that functions as a sealing surface for the lid. The package base and lid can be manufactured from metal (sheet, cast, machined), molded plastics, ceramics, or any combination thereof. Typical metal materials used to fabricate a package include stainless steel, kovar (nickel-cobalt ferrous alloy), aluminum, titanium, etc.

Package types, shapes, and designs number in the thousands. Some packages are designed to meet industry or military standards, while other packages are customized to meet manufacturer specifications. One class of package designs has an open box-style of construction. In this design class, semiconductor components can be mounted inside the open container that is then subsequently closed by sealing a lid to the base by, for example, parallel seam sealing. This sealing process is a well-known resistance welding technique that uses rolling cylindrical electrodes to create a continuous resistance weld between the edge of the lid and the seal ring and/or top surface of the sidewall of the package base. Other sealing and encapsulation processes are known and used for electronic packages and devices. Technology is being created for many other packages and devices for sensitive electronics such as, MEMS devices and advanced packaging substrates, which are difficult to stabilize during manufacturing.

Numerous technical and practical considerations provide criteria for use of package types and designs. One consideration is that a sealed package needs to be constructed in a manner that protects sensitive electronic, semiconductor, or microelectronic circuits against wear and tear, damage posed by mechanical force, as well as exposure to moisture, dirt, electromagnetic interference, and heat. Other considerations for package design include development of a sealed package that complies with government-, industry-, or manufacturer-specific requirements for product safety and regulatory standards, e.g., “MIL-STD,” “MIL-SPEC” or informally “MilSpecs.” In this regard, Milspecs are adopting more stringent standards for packages due to the high number of field failures of improperly sealed packages. The updated MilSpecs call for new test verification to confirm that sealed packages meet heightened structural and performance standards that includes use of fine leak test equipment. This type of equipment does not work with current anodized aluminum tooling for manufacturing packages. Under the updated MilSpecs, tooling is required to pass through a mass spectrometer without giving a false alarm on helium caused by gases being absorbed in package material, such as, aluminum alloys, plastic and fastening devices including screws and fasteners.

Additional considerations for package designs focus on user interface design and convenience, ease of access to internal parts and components if required for maintenance, service life, and reliability. Some practical considerations include capital cost, per-unit cost, production rate and time of delivery, and availability and capability of suppliers. Aesthetics and other marketing considerations can also play a role in final package design.

All of the foregoing considerations guide package design criteria and targeted performance goals in a variety of applications in aerospace, marine, medical, photonics, semiconductor, military, or other systems.

Package manufacturing involves numerous processes that require precise positioning and movement of a package from its unfinished to finished state along processing stations. In an example, a package and a lid often undergo a pre-assembly inspection, before the lids are placed into position to close the package. After lid placement, a lid sealing operation is performed. This can involve light tack welding to affix the lid in preparation for full sealing of the lid to the package. It is crucial that the package is properly handled and protected throughout these multiple manufacturing processes.

An effective sealing process is critical to the proper manufacture of a package. Various sealing techniques can be used to join a lid to a top surface of a side wall of a package that may include use of a seal ring to form the sealed package. Specific technologies used in the electronic packaging industry include, for example, resistance welding, projection welding, rotary welding, seam sealing, soldering, laser welding, brazing, and coating on material via sputtering, evaporation, or dispense of epoxy type materials. In some cases, the lid can be glued to the top of the opened end of the package base with a composite sealant such as an elastomer, thermoplastic, or other thermosetting adhesive/sealant. Soldering techniques implementing metal and metal alloys can be used to join the lid to the seal ring. Alternatively welding can be used to fuse the lid to the seal ring. O-rings and precision fit extruded profiles can also be used to join the lid to the seal ring.

The lid and package base material influences the sealing technique used. For example, welding, soldering, and brazing can be used to seal the same or similar materials, e.g., metal (lid) to metal (package base), plastic (lid) to plastic (package base), and plated and non-plated materials. Gluing, welding, soldering, and brazing techniques can also be used for sealing different materials, such as, for example, plastic to ceramic, plastic to metal, or ceramic to metal.

Effective seals require precise alignment of the lid relative to the upper surface and side wall of the package base, as well as a seal ring, if used. Precisely securing a package base for lid alignment and sealing is essential for hermetic seals. Improper alignment of the lid to the package base forms an incomplete, weak, and/or inconsistent seal that is detrimental to the purpose and function of the package. For other process steps in the microelectronic assembly process, it is important to maintain package devices in a repeatable alignment configuration so that the processing equipment working on the package device will secure the internal devices of the package as close as possible to each other so that the equipment will operate efficiently—if there is compensation for differences, they are very small—which results in better precision and speed.

Prior art sealing assemblies are imprecise. The prior art uses package holding tools that loosely support the bottom of a package resting on a surface during processing. One prior art device provides a package-shaped depression 14 pressed into a package holding tool 10 (see FIGS. 1 and 2). The depression 14 does not contact the side wall of the package base, thereby permitting lateral movement, as well as tipping, of the package on the top surface of the depression 14 during manufacturing. With this prior art device, forming the stamped depression 14 is time and cost intensive because stamping requires design, engineering, and multiple fabrication steps that requires trial and error to develop the finished package holding tool 10. A depression can also be machined into a piece of metal, but must then undergo finishing to render the machined surface compatible with package manufacturing processes. This adds additional cost because machining processes are expensive and require engineering time to design the finished part to be machined from raw stock. Consequently, the prior art practices significantly increase the overall cost of the package holding tool.

While processes for sealing packages varies among manufacturers, packages are generally moved from one process station to the next for treatment. For example, a package might be moved from an optical inspection station, to a lid tacking station, into an oven to bake out contaminants, then into a separate chamber that houses a parallel seam sealing device, and finally onto leak testing. Throughout any manufacturing sequence, a packages must be handled with extreme precision and care. This requires custom machined fixtures designed for each unique package variant which is costly and time consuming. Custom machined fixtures are also expensive, and, with the rapid growth and diversity of semiconductor packages, in particular, the cost and time delay become limiting factors to prior art devices, processes, and systems.

More specifically, the prior art tooling can create ineffective seals for one or more of the reasons that follow: (1) the depression 14 shown in FIGS. 1 and 2 is not flat, has a top surface on a plane that is not parallel to a plane of the top surface of the package holding tool 10, or is formed in a manner that does not permit the package to rest flat within the depression 14; (2) the package base slides, tilts, or otherwise moves relative to the depression 14 during sealing, or (3) the lid is not properly aligned with the package base as shown in FIGS. 19a and 19b due to operator error or movement of the lid and/or package base during the sealing operation. If one or more of the foregoing events occurs during the sealing operation, then it is highly probable that the seal will be incomplete and ineffective for protecting sensitive circuitry inside the electronic package from elements external to the package.

Another problem exists with prior art sealing operations. The prevailing technologies fail to provide a mechanism or process that minimizes handling of a package during manufacture. After the lid is sealed to the seal frame, the sealed package must be removed from the depression for testing, which typically requires an operator to handle the package. This can damage the package and will likely be precluded by certain manufacturing standards, such as, MIL-STD-883.

The invention addresses and solves the numerous shortcomings of the prior art by providing an improved, low cost tool for use in fabricating packages, and methods of use thereof, that: (1) implements a precision cut template that secures and aligns a package base and completed package throughout manufacturing; (2) can be machined for use secure single or multiple packages at a time; (3) can be quickly and easily laser cut to precise dimensions from suitable materials, e.g., metal or metal alloys, whereby the dimensions correspond with a profile of a package, within an acceptable tolerance, using little engineering time and at very low cost; (4) provides a reusable tool component and interchangeable parts; (5) can be used to transfer a sealed package throughout sealing and testing operations, without directly touching or handling the sealed package, thereby avoiding damage to the sealed package; and (6) specifically for microelectronic packages (including semiconductors), aligns the package cavity by means other than the base of the package—in this case by the package side walls.

The invention provides alternative approaches for package manufacture that improves upon the prior art practices of imprecise alignment, support, and handling of an electronic package. It is advantageous for internal electronics and related components of a package or device to be maintained internally and consistently at equal distances from internal surfaces of the package sidewalls rather than positioned from the bottom and align in some other method. The invention eliminates the need to use costly package-specific machining by using rapid production techniques that laser cut sheet metal plates. This new approach maintains precision and also works effectively in heated vacuum systems with minimal entrapped gases. The system components also provide a standard and convenient way to move and position the package throughout the entire manufacturing processes.

### BRIEF DESCRIPTION OF THE FIGURES

Additional aspects, features, and advantages of the invention, as to its components, structure, assembly, and use, will be understood and become more readily apparent when the invention is considered in light of the following description of illustrative embodiments made in conjunction with the accompanying drawings, wherein:

FIG. 1 shows a top perspective view of a prior art package holding tool with a stamped depression used to support a package base.

FIG. 2 shows a top perspective view of the prior art package holding tool with the package base resting in the stamped depression.

FIG. 3 shows a perspective view of a template for the tooling assembly of the invention.

FIG. 4 shows a perspective view of another template for the tooling assembly of the invention.

FIG. 5 shows a perspective view of a carrier plate for the tooling assembly of the invention.

FIG. 6 shows a perspective view of a package base.

FIGS. 7a, 7b, 7c, and 7d show perspective, side, top, and sectional views of a support base for the tooling assembly of the invention.

FIGS. 8a, 8b, 8c, 8d, and 8e show exploded, top, bottom, side, and cutaway views of a tooling assembly of the invention.

FIG. 9 shows an exploded view of another tooling assembly of the invention.

FIG. 10 shows a perspective view of the tooling assembly shown in FIG. 9.

FIG. 11 shows an exploded view of yet another tooling assembly of the invention.

FIG. 12 shows a perspective view of the tooling assembly shown in FIG. 11.

FIG. 13 shows an exploded view of yet a further tooling assembly of the invention.

FIG. 14 shows a perspective view of the tooling assembly shown in FIG. 13.

FIGS. 15a, 15b, 15c, 15d, 15e, and 15f show perspective, top, side, another side, and cutaway views of a tooling assembly of the invention.

FIG. 16 shows a tooling assembly that is securing a package base for a sealing operation.

FIG. 17a shows a preferred lid fit on the top surface of the side wall of a package base, while FIG. 17b shows an improper lid fit on the top surface of a package base that will cause arcing during a sealing operation.

FIG. 18a shows optimum alignment of a lid relative to a side wall of a package base, while FIGS. 18b and 18c show acceptable alignment of the edge of a lid offset from the side wall of a package base.

FIGS. 19a and 19b show top views of lids misaligned on package bases.

FIG. 20 shows an exploded view of another tooling assembly of the invention.

FIG. 21 shows a sectional view of the loose fit of a rivet between a template and a baseplate of a tooling assembly of the invention.

FIG. 22 shows a sectional view of a carrier having a template cut to retain a plurality of package bases.

FIG. 23 shows a sectional view of the carrier shown in FIG. 22.

FIG. 24 shows a common interface block for use with a tooling assembly of the invention, as well as processing machinery.

FIG. 25 shows a common interface block having a single alignment pin.

FIGS. 26a and 26b show top and bottom perspective views of a common interface block having two alignment pins.

FIG. 27 shows an exploded view of a tooling assembly comprising a removeable carrier.

FIG. 28 shows a side sectional view the tooling assembly shown in FIG. 27.

FIG. 29 shows a sectional view of the tooling assembly shown in FIG. 27 with a template securing a package base relative to the assembly.

FIG. 30 shows a sectional view of a tooling assembly having a template with dimples that position the template at a distance from the baseplate of the tooling assembly.

FIG. 31 shows a cutaway view of the tooling assembly shown in FIG. 30.

FIG. 32 shows a cassette holder securing multiple carriers of the invention.

FIG. 33 shows a perspective view of a tooling assembly with a template securing a package base relative to the tooling assembly.

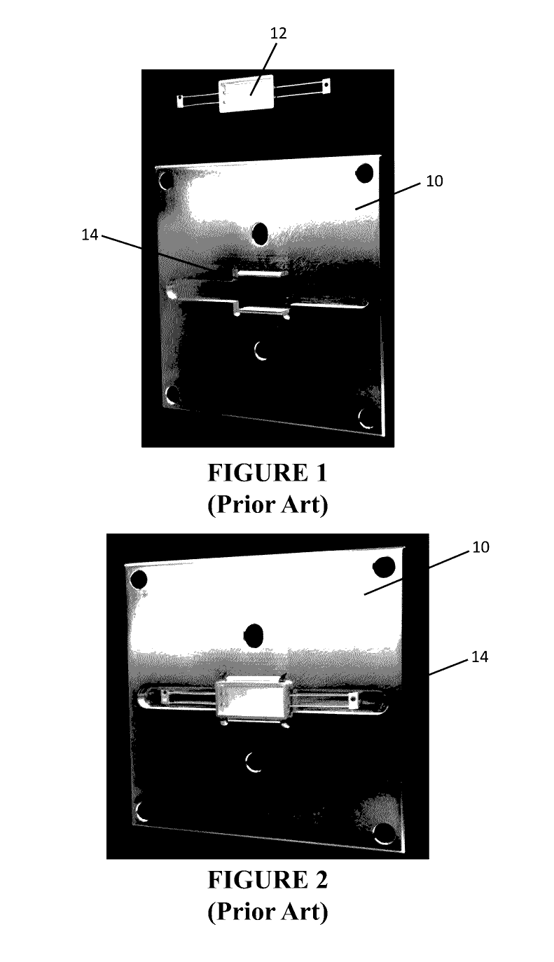

### BRIEF DESCRIPTION OF THE INVENTION

Illustrative and alternative embodiments of a tooling assembly 300, 500 that can be used for sealing, handling, and transport of electronic, microelectronic, and integrated circuit packages and other devices for housing and protecting electronics and circuitry, as well as methods of use thereof, are described in detail with reference being made to the figures of this disclosure. Although similar aspects of various embodiments of the tooling assembly 300, 500 are shown or described throughout this disclosure and are readily apparent, these similarities may be repeated within the context of the descriptions of the various embodiments of the invention, without limitation.

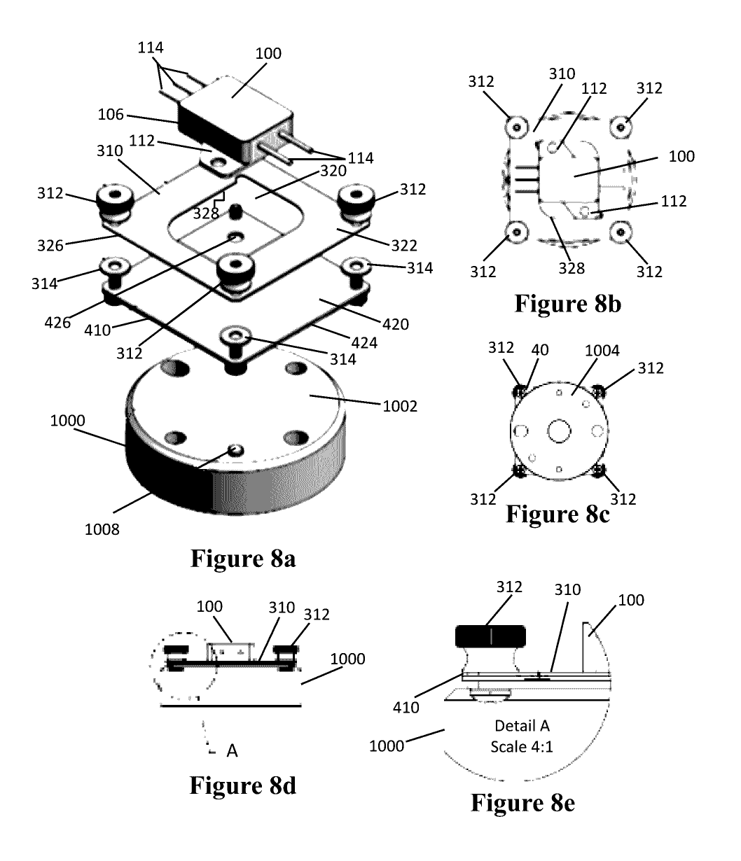

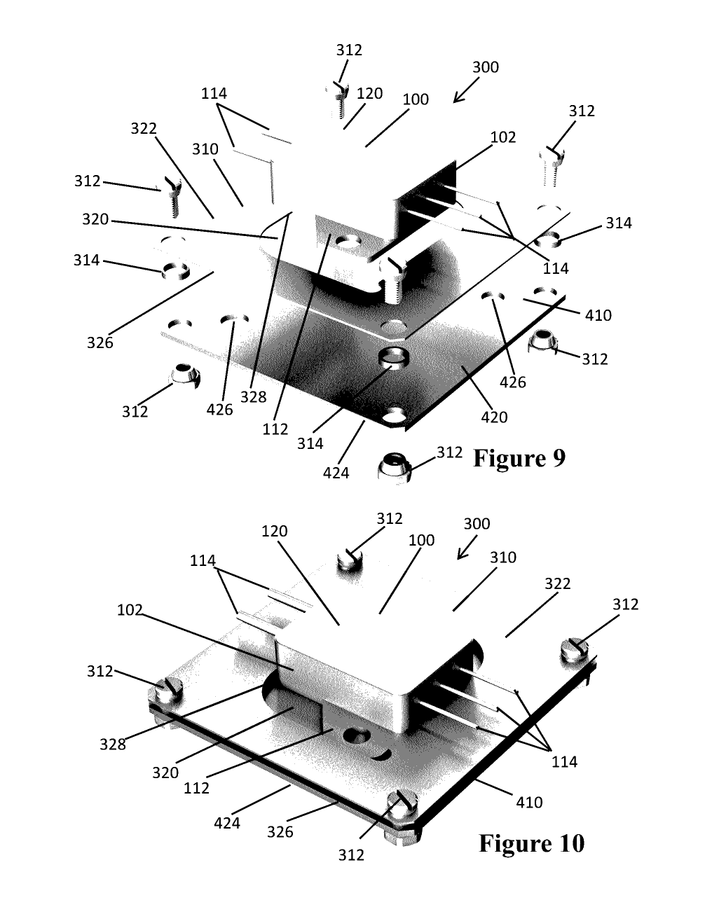

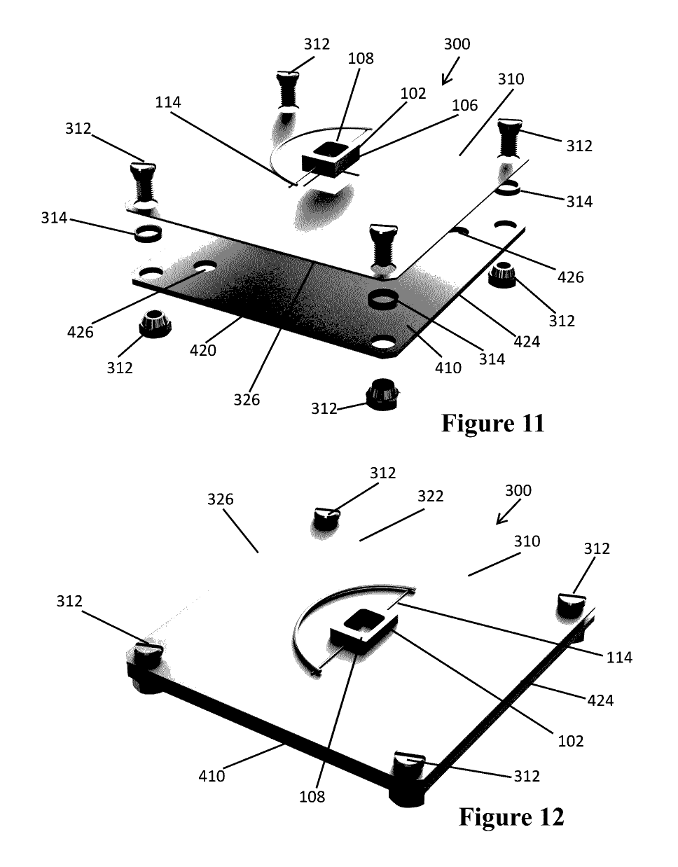

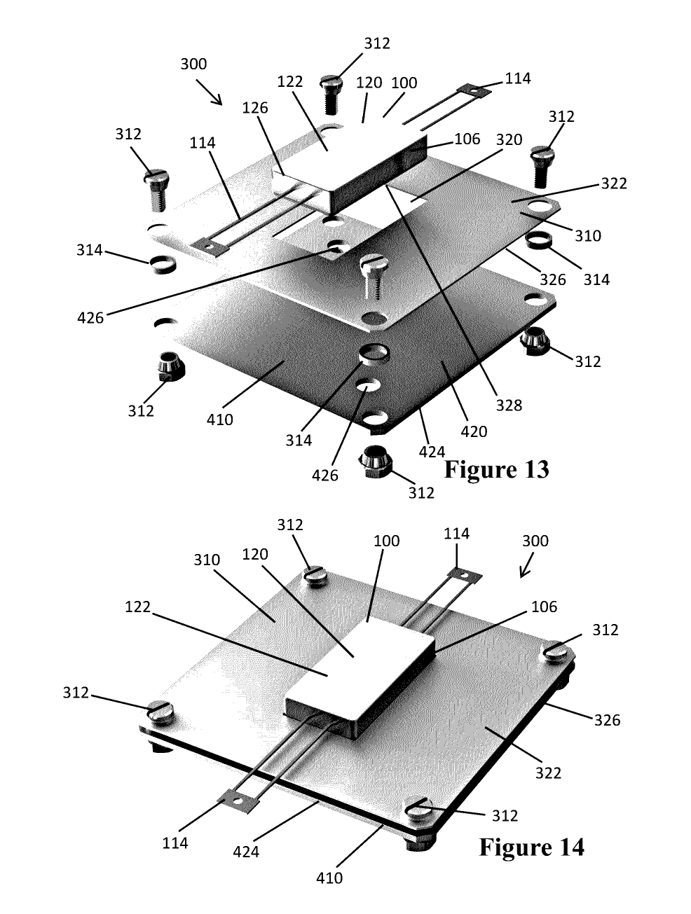

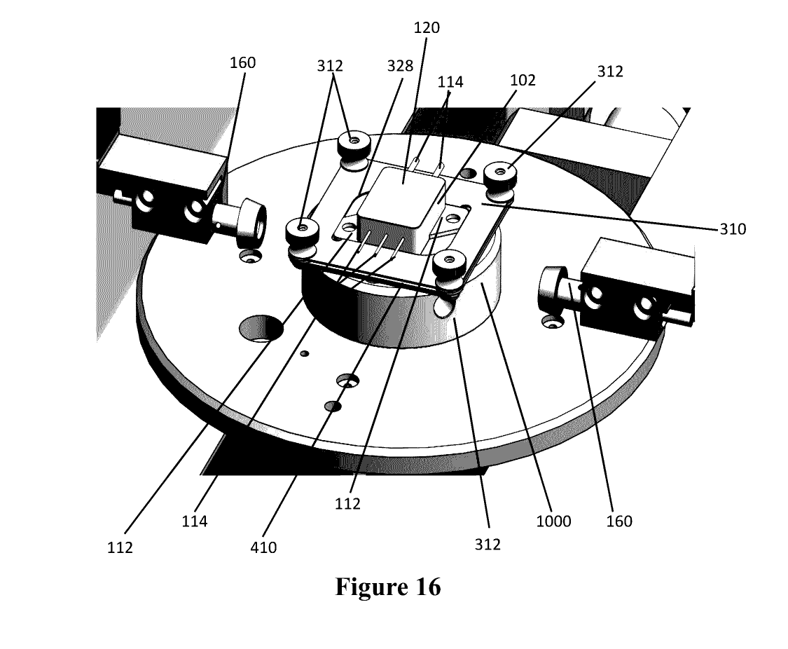

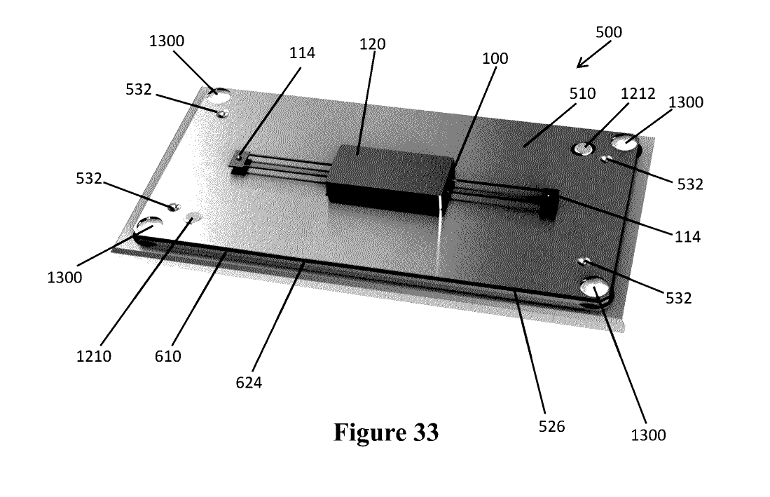

Referring generally to FIGS. 8a-8c, 9-14, 15a-15f, and 33, the invention comprises a tooling assembly 300, 500 configured to be used to manufacture an electronic package 100 that may be used in military, medical, photonics, compound semiconductors, as well as other electronics applications. The tooling assembly 300, 500 is useful for precision sealing of packages 100 (see, e.g., FIG. 16), but can also be used for other manufacturing operations such as, for example, inspection, die bonding, wire bonding, flip chip assembly, etc. Alignment of the package base 102 and lid 120, as well as the finished package 100, is critical throughout all operations, and in particular, microelectronic assembly operations. Specifically for lid sealing, the tooling assembly 300, 500 enables the side wall 106 and seal frame 108 of a package base 102, if used, to be precisely aligned with the lid 120 (see, e.g., FIGS. 18a-18c). For other manufacturing steps, such as wire bond or die bond, the tooling assembly 300, 500 places the substrate into close alignment for the prescribed operation.

The term “package” is used generally to refer to a protective enclosure containing and integrating a circuit, a microcircuit such as RF microcircuit, a semiconductor, an optoelectronic device, a sensor, or other precision electronic circuits (see, e.g., FIGS. 10, 12, 14, 33). A package 100 can comprise a lid 120, cover, or other sealing mechanism that is placed over and hermetically sealed to a package base 102 or substrate. Examples of a package 100 include an electronic package, a microcircuit package, or an integrated circuit package. Other examples of packages include any device housing or integrating sensitive electronic circuitry, such as, for example, MEMS devices and advanced packaging substrates, which may or may not be sealed with a lid 120.

The term “package base” is used generally to refer to the bottom of a package 100 having a surface 104, side walls 106, and a top surface 108, e.g., “seal frame,” of a package that define, in part, an inner compartment (see, e.g., FIG. 6). The profile of the bottom surface 104 of the package base 102 can be square, rectangular, round, oval, or other symmetrical or asymmetrical shape, and can have protruding extensions 112. The edges 102 of the package base can be pointed, rounded, or beveled.

The term “lid” is used to refer to a piece of material that is sealed, and even hermetically sealed, to the side walls 106 or seal frame 108 of a package base 102 to enclose the interior compartment of a finished package 100. The profile of the top surface 122 of the lid 102 can be any geometric shape that generally corresponds with the profile of the shape and edges of the bottom of the package base 102.

Referring now to FIGS. 8a, 9-14, and 16, the tooling assembly 300 comprises a template 310 secured by connectors 312 to a carrier plate 410. The tooling assembly 300 is configured to contact and securely hold and align a package base 102 within a communication 320 that is precision cut through the template 310, as well as a finished package 100 (see, e.g., FIGS. 10, 12, 14). The tooling assembly 300 can be used throughout seam sealing operations 160 (see, e.g., FIG. 16) or any other manufacturing step. The components of the tooling assembly 300 can be made from one or more of the following materials: metal or metal alloy (e.g., cold-rolled steel, stainless steel, kovar (nickel-cobalt ferrous alloy), aluminum, titanium, etc.), plastic, ceramic, or other rigid or semi-rigid material, in a wide variety of thicknesses. The material can be selected so that the tooling assembly 300 is light, e.g., about 35 grams or other weight. In embodiments, the metal used to make the template 310 and/or the carrier plate 410 can be thin. The thinness of the material makes the overall tooling assembly 300 easily transportable.

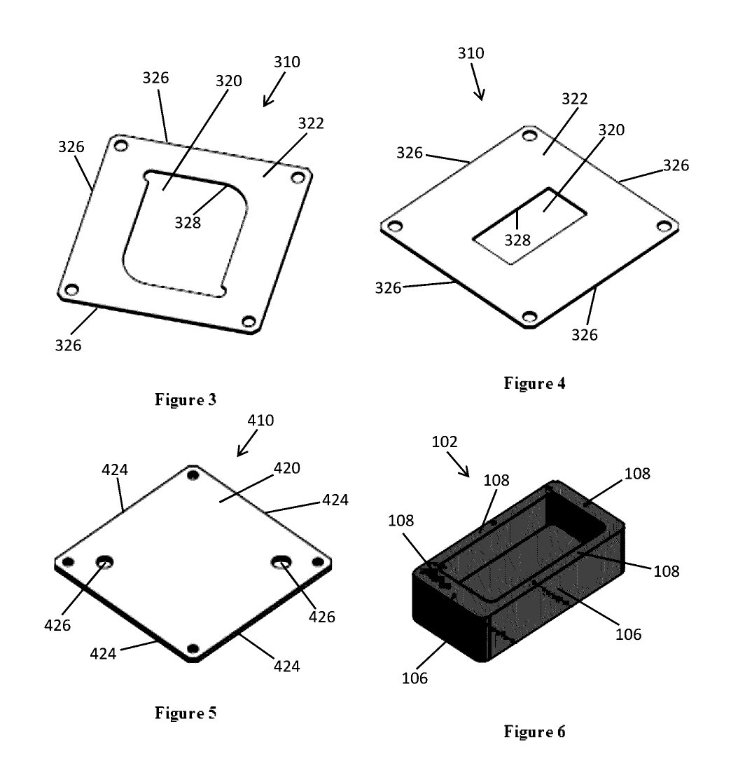

Referring to FIGS. 3, 4, 9-14, and 16, the template 310 is a generally flat piece of material having a precisely cut communication 320 from the top surface 322 to the bottom surface 324 of the template 310. The external profile defined by the external edges 326 of the template 310 can have any shape and typically has the same or similar external profile as the external edges 424 of the carrier plate 410 as shown, for example, in FIGS. 10, 12, and 14.

Turning now to FIGS. 3-4, 8a, and 9-14, the communication 320 is defined by an inner peripheral edge 328. This inner peripheral edge 328 can be perpendicular to, or provided at an acute or obtuse angle to, the top surface 322 and/or bottom surface 324 of the template 310. The face of the inner peripheral edge 328 can be flat, rounded, or beveled. During manufacture of the tooling assembly 300, the communication 320 is cut precisely so that the inner peripheral edge 328 will contact, in whole or in part, an external portion of the side walls 106 of a package base 102 that is resting on the top surface 420 of the carrier plate 410, as well as, if present, extensions 112 protruding from the package base 102. The same or similar features can also be present in other embodiments of the communication 520 of the template 510 for use with the tooling assembly 510.

The size of the communication 320 can be the same as, or slightly larger or smaller than, the perimeter of the bottom of a package base 102. In any case, the size difference between the package base 102 and the communication 320 can be within an acceptable tolerance (plus or minus) that can range from about 50 to about 250 microns or other distance acceptable to a manufacturing specification. In all embodiments, the communication 320 is configured to receive and to directly contact the side walls 106 of the package base 102, see, e.g., FIGS. 10, 12, 14, 16, in a precise position that prevents side-to-side movement, tipping, or rocking of the package base 102, as it rests on the top surface 420 of a carrier plate 410, as well as during manufacturing processes, such as, for example, a sealing operation 160.

The shape profile of the communication 320 can mirror the profile of the shape of an external view of a bottom surface 104 of a package base 102 (see, e.g., FIGS. 4, 12, 14) or have an alternative shape profile (see FIGS. 3, 8a, 10) so long as the communication 320 is sized and shaped to contact a sufficient portion of the external periphery of the side walls 106 of the package base 102, or other extension 112 or projection from the package base 102, to sufficiently secure the package base 102 in the tooling assembly 300.

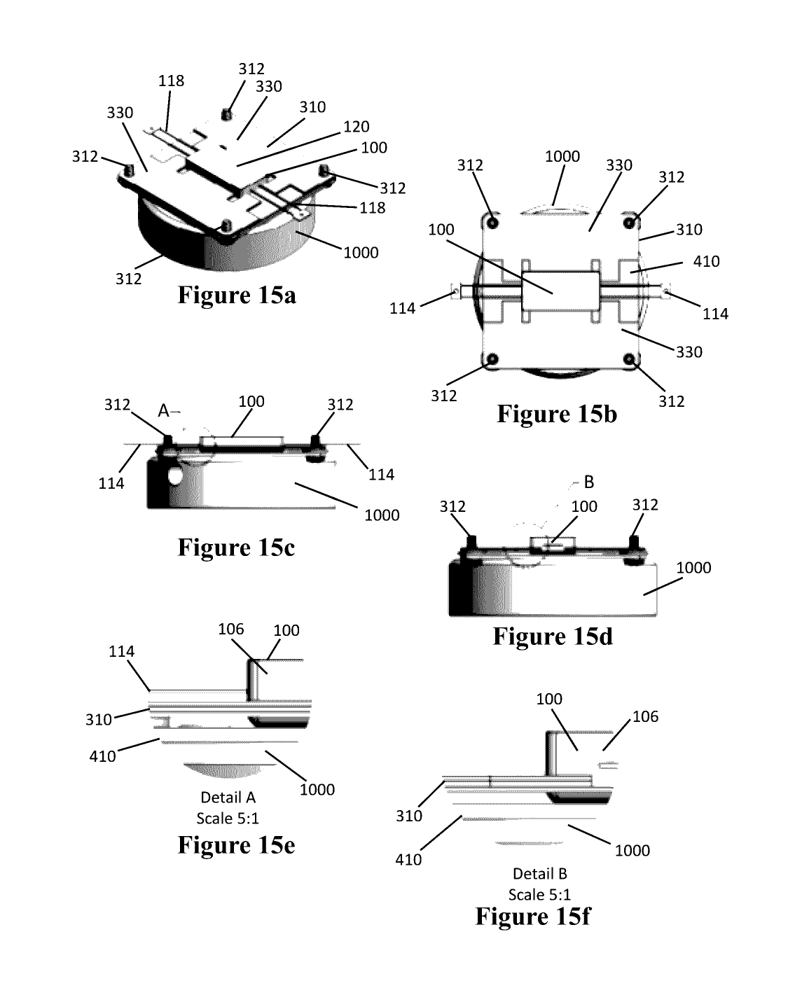

In an alternative embodiment shown in FIGS. 15a and 15b, the template 310 can comprise two or more subparts 330 that, when fastened to the carrier plate 40, define a precisely cut communication 122 that receives and secures a package base 102. The two or more subparts 330 can include reliefs for wires, components, or other structures 114 extending away from the package base 102 as shown in FIGS. 15a-15c, or odd or irregularly-shaped package bases.

Referring now to FIGS. 5, 9, 11, and 13, the carrier plate 410 includes a generally flat piece of material that has at least two mounting holes 426 in at least its bottom surface 422. The external edge profile 424 of the carrier plate 410 can have any dimension including, but not limited to, the same or similar external edge profile 326 of the template 310, see, e.g., FIGS. 10, 12, and 14. In an embodiment, the carrier plate 410 comprises a heat conducting metal, such as copper, that can function as a heat sink to dissipate heat that arises during a seam sealing operation 160. One or more holes provided in an alternative carrier plate 410 can provide additional heat dissipation functionality.

The use of a flat carrier plate 410, with or without holes, can be optimized for heat sinking by flowing either warm or cold air at the carrier plate 410 to control the temperature of the package base 102 before, during, and after a sealing operation 160. For a standard weld seal, the configuration of the carrier plate 410 can be used to cool the package 100 so that the weld joints could also be cooled for better joining. For solder sealing, the configuration of the carrier plate 410 could be used to warm the package base 102 for a more gradual heating profile for solder reflow.

The template 310 and the carrier plate 410 can be assembled together with fasteners 312 as shown in FIGS. 8a and 15d, vented screws (to avoid trapping gas), or tack welding based upon manufacturing requirements. Tack welding renders the tooling assembly 300 compatible with mass spectrometers used in the fine leak testing of hermetically sealed packages. In alternative embodiments, fasteners 312 such as threaded bolts shown in FIGS. 8a-8c or vented screws engage corresponding threads in the template 310 and in the carrier plate 410 that secure the template 310 to the carrier plate 410. In either case of implementing welding or using fasteners 312, the bottom surface 324 of the template 310 and the top surface 420 of the carrier plate 410 can be in contact, or can be spaced at a distance as shown in FIGS. 8d, 8e, 10, 12, 14, 15e, and 15f, whereby that distance is less than the height of the package base 102.

Referring now to FIGS. 8d, 8e, and 9-14, the fasteners 312 connect the carrier plate 410 to the template 310 and can include additional components. Specifically, each fastener 312 can include a spacer 314 to preset a separation or gap between the template 310 and the carrier plate 410 as shown in FIGS. 8a, 9, 11, and 13. In one embodiment, the fastener 312 can be removable, permitting the carrier plate 410 and the template 310 to be separated or joined at the discretion of an operator. The fasteners 312 also permit different templates 310, which are cut specifically to types of a package base 102, to be interchanged with the carrier plate 410.

In all embodiments, and as shown particularly in FIGS. 10, 12, 14, and 15a, the template 310 precisely holds and secures the package base 102 in a position in which the bottom surface 104 of the package base 102 rests on the top surface 420 of the carrier plate 410. This configuration functions to maintain the package base 102 in place relative to the tooling assembly 300 so that the package base 102 does no slide, rock, wobble, tilt or tip over. This positions the package base 102 for alignment with a lid 120 for sealing. Lid alignment can occur anywhere vertically relative to the side wall 106 of the package base 102. For lid alignment, the level of height of the template 310 relative to the package base 102, as it rests on the carrier plate 410, can be preset or adjusted to a desired height based, in part, on the height of the electronics inside the package 100, as well as the wires, components, or structures 114 extending externally from the package 100. In an embodiment, the top surface 322 of the template 310 support wires, components, or structures 114 extending from the package 100.

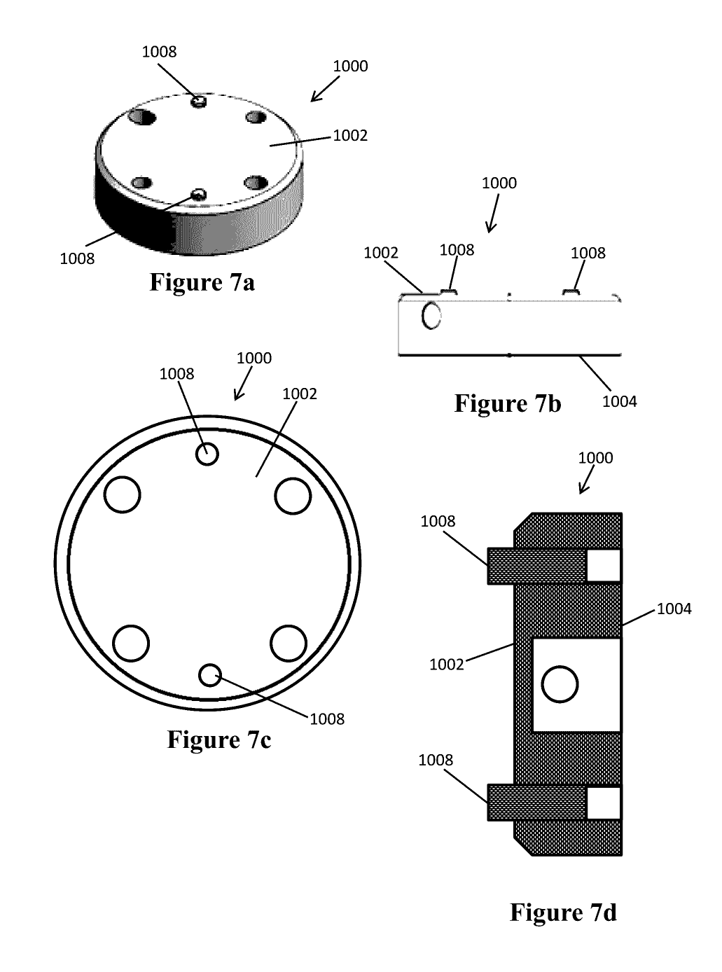

Referring to FIGS. 7a-7d, 8a-8e, 15a-15f, and 16, the tooling assembly 300 includes a base 1000 that can be permanently or removeably mounted relative to a sealing operation 160. In an embodiment, the base 1000 is cylindrical, but can be any geometric shape. Disposed on the top surface 1002 of the base 1000 are mounts 1008 that extend vertically and are configured to precisely engage receiving holes 426 of the carrier plate 410. The mounts 1008 and receiving holes 426 hold the carrier plate 410 in a fixed position relative to the base 1000. In alternative configurations, receiving holes can be provided in the base, while the mounts 1008 are formed on the bottom surface 422 of the carrier plate 410. The bottom surface 1004 of the base 1000 can be used as a universal interface for manufacturing machinery.

The components of the tooling assembly 300, 500 can be fabricated using any number of processing methods including, but not limited to, traditional machining, stamping, punching, or cutting, or more preferably laser cutting or CNC. Specifically, the communication 320, 520 can be cut out of a blank for the template 310, 510 by laser, CNC machine, or other cutting apparatus capable of precisely cutting the template material using an engineering calculation that defines the precise dimensions of the communication 310, 510 within an acceptable tolerance of the external dimensions of the package base 102. The cutting operation can be controlled by CAD software and engineering design files that define dimensions for the communication 320, 520. The template 310, 510 can be machined to include one or more communications 320, 520 so that the tooling assembly 300, 500 can be used to seal and manufacture single or multiple electronic packages 102.

The fabrication and assembly of the tooling assembly 300, 500 can be quickly and economically completed in comparison to the fabrication and assembly of the prior art tooling. In particular, laser cut processing provides the lowest cost for materials and quickest operation. Laser cutting is a cleaner process when compared to machining and does not require use of heavy equipment for punching operations. Laser cutting enables the final package 100 that is produced to have the tooling precisely measured and quickly fabricated in accord with the actual engineering drawings for the package 100. Laser cutting also can be used to create a precision fit between a specific template and package base. This takes away trial and error and expensive engineering and fabrication steps typically found in the prior art tooling. Additionally, the materials used to fabricate the tooling assembly 300, 500 can be easily recycled after use and, in some cases, can be re-used with only an additional cut to the material. The fabrication also permits the development of edge grips on the packages 100 that may be static or adjustable.

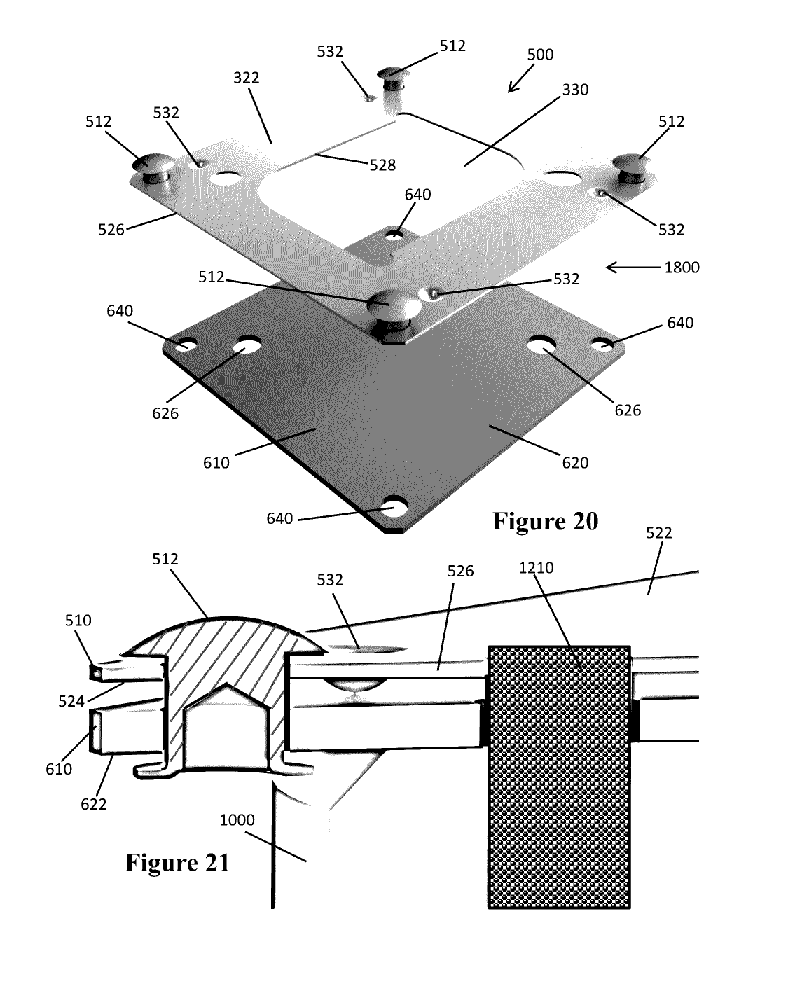

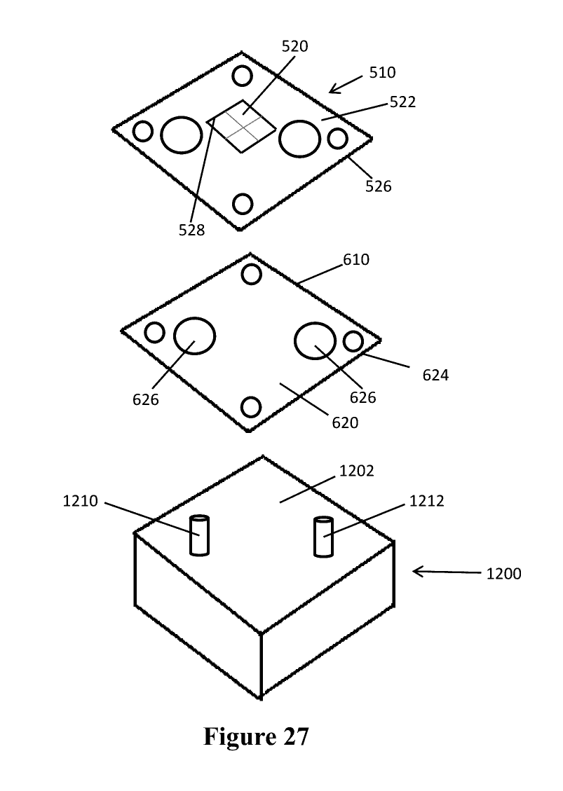

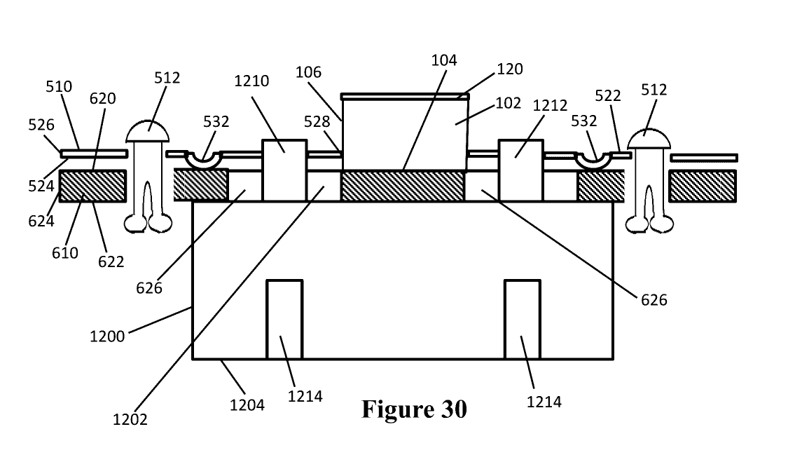

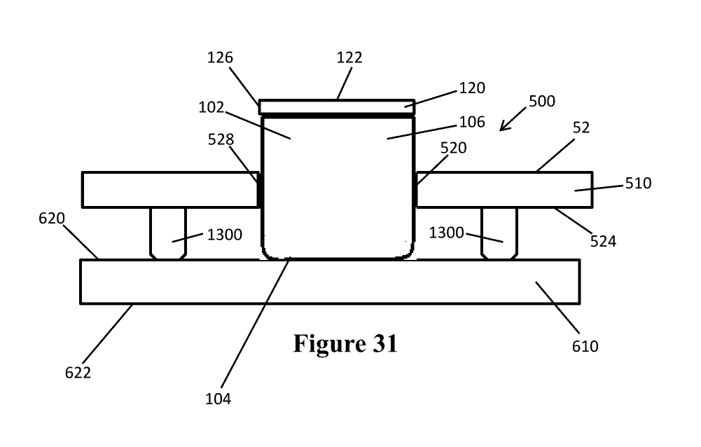

Since a package 100 will be moved sequentially through a variety of process equipment developed by various manufacturers, a standard or common mechanical interface between the tooling assembly and the process equipment is needed. An alternative embodiment of the tooling assembly 500 provides a common interface block (CIB) 1200 and a carrier 200 comprising a template 510 and a baseplate 610 (see, e.g., FIGS. 20-31, 33).

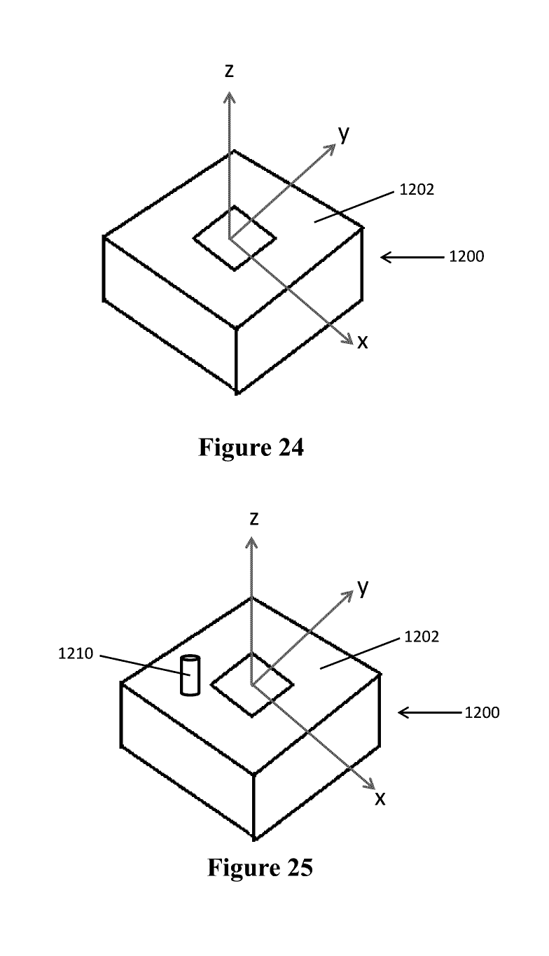

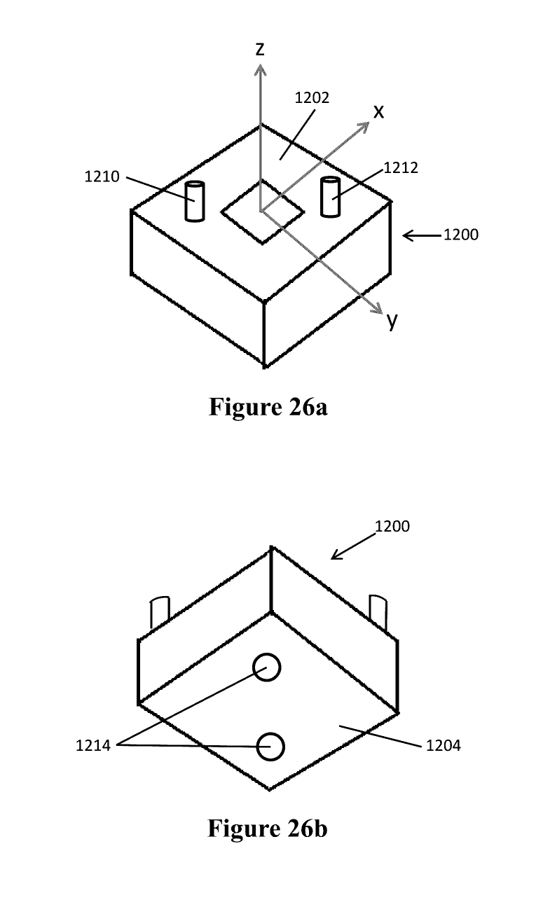

Turning now to FIGS. 24-28, the common interface block (CIB) 1200 is a machined block or base that has on its bottom surface 1204 (see FIG. 26b) features configured to engage with the various process stations, while also providing on its top surface 1202 a universal means of releaseably securing a baseplate 610 of the tooling assembly 500. For example, the CIB 1200 can be a prismatic metallic block that can be anodized aluminum, stainless steel, or other durable metal or other material. The CIB 1200 has two parallel flat surfaces, e.g., top surface 1202 and bottom surface 1204. These flat surfaces are finely machined surfaces that establish the CIB 1200 and position a package base 102 precisely at X, Y, and Z axes. The CIB 1200 can comprise various processing machines and systems that use mechanical features to position the tooling assembly 500 on X, Y, and Z axes within a dimension work space of process station, e.g., a sealing operation 106.

The center of a package base 102 can be located at an intersection of X, Y, and Z axes in a dimension of a processing station. In alternative embodiments, the package center can be offset from the intersection of the X, Y, and/or Z axes. In any embodiment, the X, Y, and Z axes are zeroed within in the dimension and aligned with mechanical and software controls of a manufacturing process.

In addition to the top surface 1202 of the CIB 1200 that rests on the X and Y axes, the CIB 1200 can include a pin 1210 that extends vertically from the top surface 1202 of the CIB 1200, see, e.g., FIGS. 21, 25, 26a-26b, 27-28, and 30. The purpose of the pin 1210 is to fix the center of the baseplate 610 relative to the intersection of the X and Y axes of the CIB 1200. While one pin 1210 locates the center of the baseplate 610 with respect to the CIB 1200, the use of one pin 1210 permits rotational movement of the baseplate 610 about the pin 1210 itself. Of course, the pin 1210 restricts movement of the baseplate 610 along the X and Y axes of the top surface 1202 of the CIB 1200 if the baseplate 610 rests on the top surface 1202 of the CIB 1200, see, e.g., FIGS. 21, 28, and 30. In embodiments shown in FIGS. 26a-26b, 27, 28, and 30, a second pin 1212 can also extend from the top surface 1202 of the CIB 1200 to eliminate rotational movement of the baseplate 610 about the first pin 1210. The first pin 1210 and the second pin 1212 can be used to fix the tooling assembly 500 and, incidentally, a package base 102 at X, Y, and Z axes of a processing dimension so that the center of the package base 102 center is precisely positioned and location controlled and referenced relative to the center of a dimension work space of process station.

Additionally, one or more holes 1214 are provided in the bottom surface 1204 of the CIB 1200 so that the CIB 1200 can be precisely located on the specific process machine, e.g., seam sealer (see, e.g., FIG. 26b, 30), relative to the center the processing dimension of that machine. The bottom surface 1202 of the CIB 1200 can have mounting features configured to mate with the variety of process equipment, while the top surface 1202 of the CIB 1200 has standard mounting features (one or two pins 1210, 1212) that mate with a baseplate 610. In an embodiment, the one or more holes 1214 in the bottom surface 1204 of the CIB 1200 can be a slot. The slot can prevent rotation of the CIB 1200 relative to its interface with a support surface of a work station of a process machine. In alternative embodiments, and in addition to the slot/hole other structural features can be included to align and/or fix the CIB 1200 to the process station.

Similar to other embodiments, see, e.g., FIGS. 20, 22-23, 30, and 33, the laser cut sheet metal parts of the carrier 1800 can be used to precisely locate and support the package base 102. The baseplate 610 can be a sheet metal plate of desired thickness. The baseplate 610 can rest on top of the CIB 1200, see, e.g., FIGS. 21, 28, 30. Up to four cutouts or holes 640 (, see, e.g., FIGS. 20, 21, 30) can be provided in separate corners of the baseplate 610, in addition to two clearance holes 626 that the pins 1210, 1212 of the CIB 1200 protrude through. The clearance holes 626 provide substantial clearance around the pins 1210, 1212. It is important that the baseplate 610 is flat and the top surface 620 and bottom surface 622 are substantially parallel to each other. The baseplate 610 is a standard feature for all carriers 1800 of a given family size.

Similar to other embodiments of the invention, the next plate is the top plate or template 510, see, e.g., FIGS. 20-23, 28, 31. The template 510 also has holes 524 to receive and engage the pins 1210, 1212 extending from the top surface 1202 of the CIB 1200 and through the baseplate 610. Instead of the larger clearance holes 626 in the baseplate 610, the holes 524 are close fitting with the corresponding pins 1210, 1212 protruding through the baseplate 610. In an embodiment, one of the holes 524 can be slot shaped. In all embodiments, the holes 524 in the template 510 engage the pins 1210, 1212 and completely lock and precisely locate the template 510 with the CIB 1200. When the template 510 is securely positioned by the pins 1210, 1212, see, e.g., FIGS. 21, 28, 30, the baseplate 610 remains free to slide around underneath the template 510 within the limits established by the large clearance holes 626 in the baseplate 610.

The template 510 and baseplate 610 can be attached to each other using blind tubular rivets 1300 to form a carrier 1800, see, e.g., FIGS. 20-21, 22-23, 30. Other fasteners can be used, but rivets 1300 are preferred because gases are not trapped in the rivet 1300, as can occur with threaded fasteners. The rivets 1300 fit into slightly oversized holes of the baseplate 610 and template 510, and do not need to be fully swaged or clinched. The rivets 1300 are loose in their holes and can move up and down within the confines of the two plates. This loose fitment of parts is an important design feature that also eliminates the possibility of gases being entrapped within the tooling assembly 500. This is a valuable feature because the tooling assemblies are often placed in a vacuum chamber and pumped down for leak checking. Any entrapped gases can vastly increase the time required to achieve acceptable vacuum levels. The loose fitting of the baseplate 610 and template 510 with rivets 1300 addresses this issue.

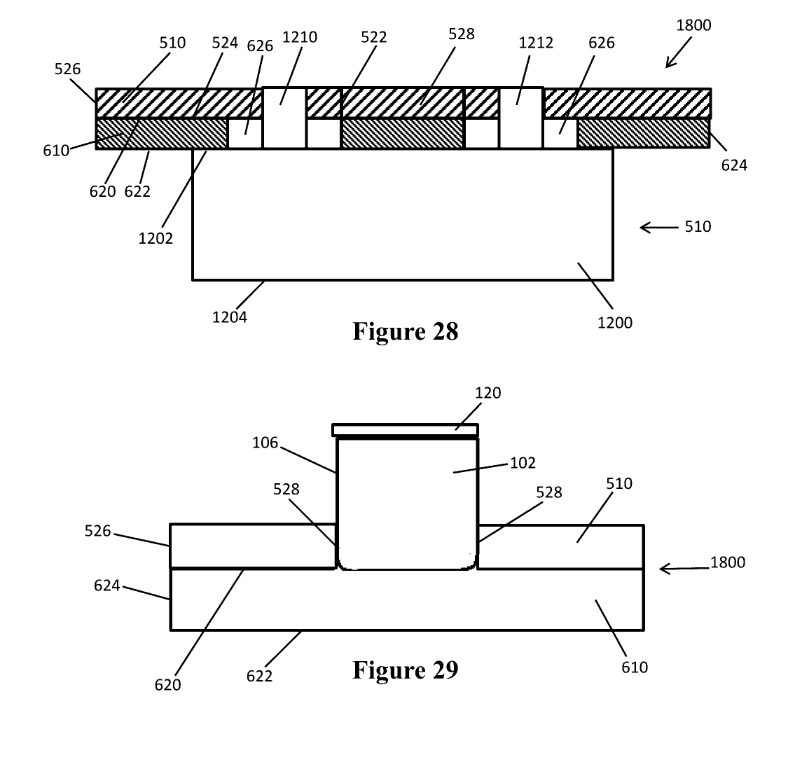

In other embodiments, see, e.g., FIGS. 20-23, 30, 33, a design of the template 510 or the baseplate 610 can include small bumps or dimples 522 that space the template 510 and baseplate 610 from one another. In addition to fully eliminating the chance for entrapped gases between the adjacent baseplate 610 and template 510, the dimples 522 also serve a functional purpose when it comes to holding and securing the package base 102. If there were no dimples 522, then the template 510 can rest directly on top surface 620 of the baseplate 610, as shown specifically in FIGS. 28 and 29.

Referring now to FIGS. 20-23 and 30, the template 510 can be relatively thin (e.g., about 0.015 inches) for the ease of rapid and affordable laser cutting. The minimal thickness of the template 510 provides little depth or contact area for the retention and security of the package base 102. In fact, some packages 100 have radiused bottom surfaces 104 and therefore would not be retained by the template 510 at all. The dimples 524, if present, see, e.g., FIGS. 21-23, 30, raise the template 510 up off the baseplate 610 providing more stability and a more secure grip onto the side walls 106 of the package base 102. The dimples 524 are easily created into the thin template 510 or baseplate 610 using inexpensive dies and presses. The depth and the style of the dimple 524 can be adjusted as required to provide a varying distance between the baseplate 610 and template 510.

This invention also provides for the use of several templates 510 stacked atop each other and secured to one another by pins 1210, 1212 that extend from the CIB 1200. As long as the dimple 524 features do not axially coincide, it is possible to use multiple tiers of templates 510. This approach is useful to retain and support a package 100 with an unusual design or cross-section.

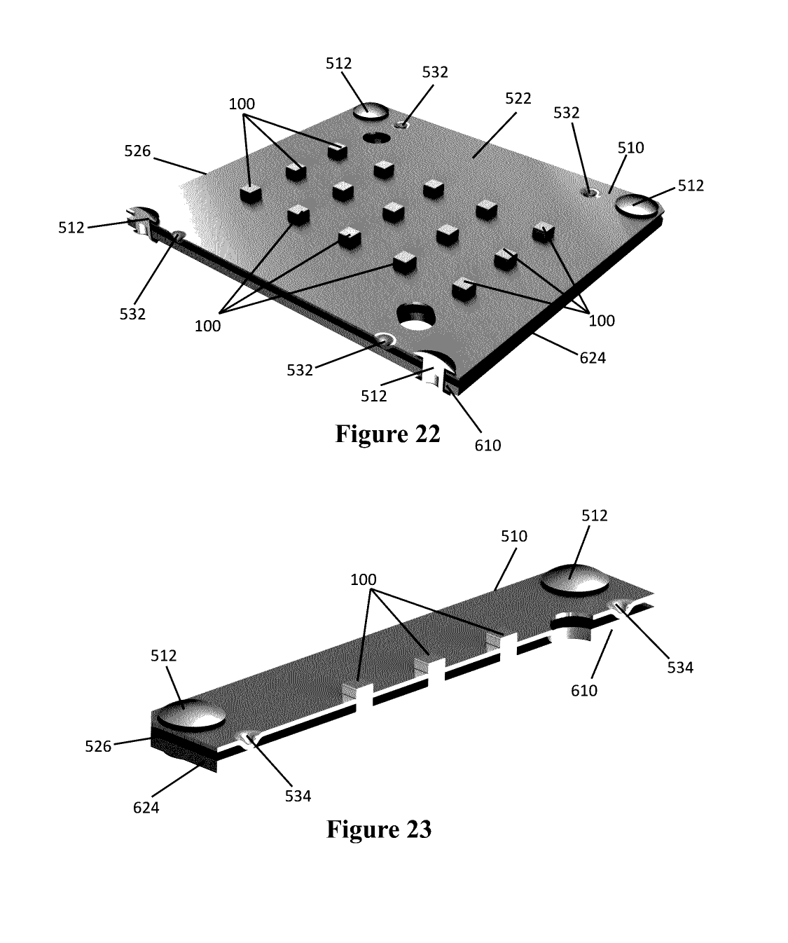

The baseplate 610 and template 510 connected as a carrier 1800, see, e.g., FIGS. 22-23 and 30, can be lifted off of the CIB 1200 and moved to subsequent process stations. Alternatively, the CIB 1200 could be lifted off the process station and moved along with the baseplate 610 and template 510 resting on top.

Provided with the invention are methods for assembling the tooling assembly 300, 500 and for using the tooling assembly 300, 500 in processing operations.

Methods for forming the tooling assembly 300 are provided. The methods include forming the tooling assembly 300 comprising a template 310 with the internal peripheral edge 328 of a communication 320 configured to engage sidewalls 106 of a package base 102, and a carrier plate 410 that is configured to engage a base of process machinery. This method comprises providing a template 310 having a precise laser cut communication 320 defining the internal peripheral edge 328 configured to fit a package base 102 and then securing the template 310 to a carrier plate 410 using any one or more fasteners 312. The step of securing the template 310 to the carrier plate 410 can include placing spacers 314 between the template 310 and the carrier plate 410, thereby forming a gap space between the template 310 and the carrier 410 for the purpose of securing a package base 102 with the tooling assembly 300.

Methods for using the tooling assembly 300 are also provided. The methods generally include precisely aligning a package base 102 relative to a manufacturing process operation to form an effective seal between a lid 20 and the seal frame 108 of the package base 102. The aligning step includes positioning the lid 120 on the upper surface 108 of a package base 102 so that the outer edge 126 of the lid 120 is either aligned with, or closely aligned to, the vertical surface of the side walls 106 of the package base 102. Upon proper alignment of the lid 120 and the package base 102, a seal can be formed with a seam sealing operation 160, e.g., parallel seam sealing as shown in FIG. 16. Prior to forming the seal, tack welds can be used to first secure the lid 120 in a fixed position relative to the package base 102. The seal comprises a joint that is continuous, overlapping, or in a line progressing around the upper edge of the package base 102.

During a sealing operation 160, the method includes positioning the package base 102 within the communication 320 of the template 510 such that at least a portion of the exterior sidewall 106 or projections 112 of the package base 102 contact the interior peripheral edge 328 of the communication 320 shown in FIGS. 10, 12, 14. With the package base 102 positioned in the communication 320, the internal peripheral edge 328 of the communication 320 secures the package base 102 in a fixed position relative to the template 310, and the bottom surface 104 of the package base 102 rests on the top surface 420 of the carrier plate 410. The secured package base 102 is then calibrated relative to the dimension of a process station for a manufacturing step. The fit between the package base 102 and the template 310 is such that the package base 102 can vertically slide in and out of the communication 320 without having to force the fit, but with little clearance (see, e.g., FIGS. 10, 12, 14) that prevents side-to-side movement or tipping of the package base 102 relative to the template 310 during processing and transport.

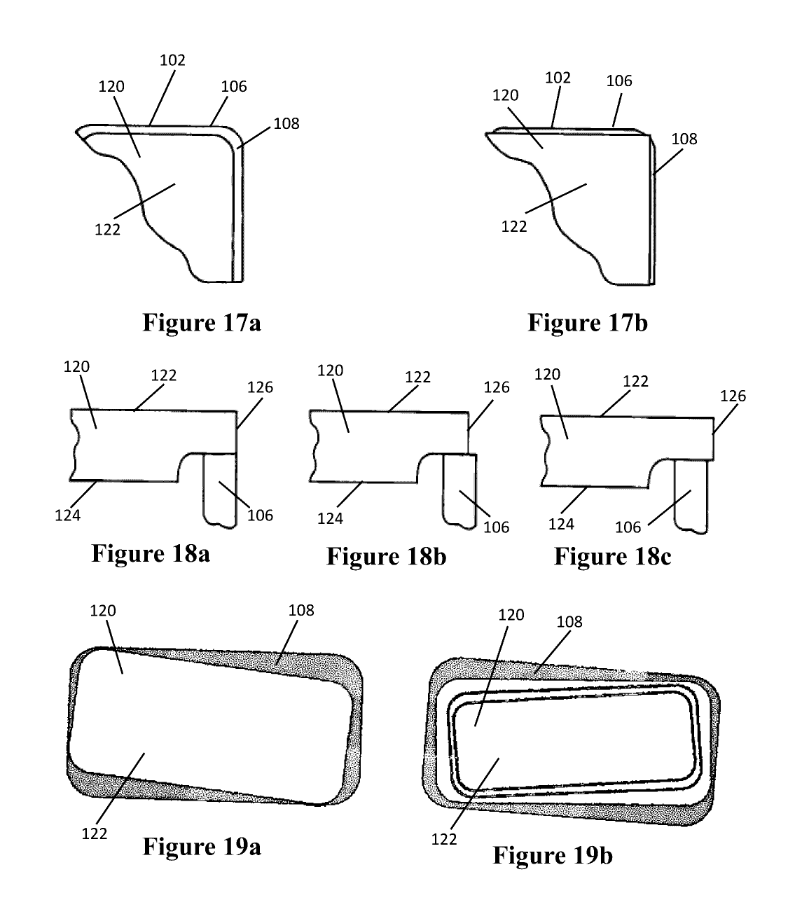

Referring now to FIG. 8a, the method includes engaging the receiving holes 426 of the carrier plate 410 with mounts 1008 of a base 1000 so that the mounts 1008 secures the tooling assembly 300 and the package base 102 in a position relative to the seam sealing operation 160. At this point of the sealing process 160, with the internal circuitry in place, the method includes placing a lid 120 on the upper surface 108 of the package base 102 and then aligning the outer edge 126 of the lid 120 with the side walls 106 of the package base 102 as shown in FIGS. 16, 17a, and 18a-18c. With the lid 120 in place, but not yet sealed, the internal atmosphere of the unsealed package 100 can be modified from ambient air to include inert or other gases such as argon, nitrogen, or a mix of gasses like argon with helium, to adjust moisture levels of the ambient air, to form pressure that is ambient, lower (vacuum) or higher (pressurized), or to provide preferred conditions for the circuitry. With the lid 120 aligned, and the internal atmosphere set, the method includes the step of forming a seal between the upper surface 108 of the package base 102 and the outer edge 126 of the lid 120 that hermetically seals the lid 120 to the package base 102.

The sealing operation 160 can include using heat from various sources. For example, heat can be generated by way of electrical current, or by directing concentrated light or heated air or gasses onto the lid 120 and the package base 102. The heat fuses or seals the lid 120 to the package base 12. Electrical energy and current can be generated by passing a DC or AC current through the parts for heating time that is typically short to fuse the lid 120 to the package base 102. This can occur by way of parallel seam sealer for example, whereby the lid 120 and the package base 102 are held with an electrode that positions the parts, feeds the electrical current to the parts and pushes the parts together. The electrode can have a shape or cavity, to hold the lid 120 to the package base 102. It can also be a wheel that rolls over the intended location of the joint.

Light energy can be generated by a laser that can be focused onto a small spot to melt metal or plastic and moved around the external edge 126 of the lid 120 to seal the lid 120 to the package base 102. The laser can be continuous or pulsed. Laser welding is a contact free process that requires the lid 120 to be held in place relative to the package base 102 with external tooling. The tooling holds the lid 120 in place so that the laser can make a few tacks around the edge of the lid 120 to secure it to the package base 102. After these tacks are made, and the tooling is removed, the seam can be completed by the sealing operation.

Other sealing processing can include forming a pure weld by fusing the lid 210 and the package base 102, brazing that melts a third interposer metal present as a coating, soldering which melts a third metal having a low melting temperature, e.g., maximum of 300° C., or adhesion formed by an adhesive such as an thermosetting adhesive.

In alternative embodiments, the invention provides methods for forming an alternative embodiment of the tooling assembly 500 that comprises a template 510, a baseplate 610, and a common interface block 1200. The method includes the steps of centering a baseplate 610 relative to a common interface block 1200 using a pin 1210 (see, e.g., FIGS. 21, 28, 30) that extends from and is positioned at the center of a top surface 1202 of the common interface block 1200 and engages with corresponding receiving holes 626, 524 or indents in the baseplate 610 and template 510.

An alternative embodiment of the method includes contacting the baseplate 610 with the common interface block 1200 with the base plate 610 with the center pin 1210, see, e.g., FIGS. 21, 28, 30. The step of centering the baseplate 610 with the common interface block 1200 can include using a second pin 1212 that also extends from the top surface 1202 of the common interface block 1200 and engages a hole 626 or indent in the baseplate 610.

The method includes the further step of aligning a template 510 with the baseplate 610 and common interface block 1200 by positioning the pins 1210, 1212 extending from the common interface block 1200 in precision cut receiving holes 524 or detents of the template 510, see, e.g., FIGS. 21, 28, 30. This aligning step locks the template 510 to the common interface block 1200.

In an embodiment, the method includes the step of providing the baseplate 610 secured loosely with rivets 1300 to the template 510 to form a carrier 1300, see, e.g., FIGS. 20-23, 30.

The invention also provides methods for using the tooling assembly 500 in a processing method. This method includes placing a bottom surface 105 of a package base 102 on a top surface 620 of a baseplate 610 and securing the package base 102 with templates 510 that contact external side walls 106 of the package base 102 in a manner that prevents lateral movement of the package base 102 along the X and Y axes of the top surface 620 of the baseplate 610 and/or tipping of the package base 102 as it rests on the top surface 620 of the baseplate 610. The method includes the further step of resting the tooling assembly 500 in a secured manner on one or more processing machines used to assemble a package 100. Depending on the process step, the tooling assembly 500 can be positioned statically or dynamically relative to a processing machine that performs any one or more assembly steps to complete the package 100. For example, the tooling assembly 500 may be held in a static position relative to processing apparatus while a lid 120 is placed and aligned precisely on the package base 102 and then optionally spot welded prior to sealing the lid 102 to the package base 102 with a seam sealer in order to form an effective seal. Alternatively, the package base 102, as well a finished package 100, can be moved relative to the processing apparatus in connection with any one or more steps of placing the lid 120 on the package base 102, the optional spot welding, and the seam sealing.

In another embodiment, the tooling assembly 500 can be used in a processing method that includes locking the tooling assembly 500 comprising a common interface block 1200 by aligning pins 1210, 1212 through a baseplate 610 with a template 510, whereby the template 510 is locked by the pins 1210, 1212 with the common interface block 1200, see, e.g., FIGS. 21, 28 and 30. In alternative embodiments, the method includes stacking one or more additional templates 510 on top of the locked template 510.

The method includes the further step of positioning the bottom surface 124 of a package base 102 on the top surface 620 of the baseplate 610 by securing the package base 102 along an aspect of its side walls 106 with an internal peripheral edge 528 of a communication 520 of the template 510, thereby preventing lateral movement of the package base 102 along the X and Y axes of the top surface 620 of the baseplate 610 and/or tipping of the package base 102 as it rests on the top surface 620 of the baseplate 610. The positioning step includes centering the package base 102 on the X, Y, and Z axes of the tooling assembly 500, see, e.g., FIGS. 29, 30, 31, 33.

The method includes the further step of resting the bottom surface 1204 of the common carrier block 1200 on a receiving surface of a process machine with holes 1214, slots or indents of the common interface block 1200 that engage corresponding protrusions of the receiving surface, see, e.g., FIGS. 21, 28, 30. The tooling assembly 500 can be positioned statically or dynamically relative to a processing machine that performs any one or more assembly steps to form the package 100.

In a further embodiment, the invention provides a method for manufacturing an package 100 by releaseably securing a package base 102 in a tooling assembly 500 for processing the package base 102 with other components and parts into a finished form for use, see, e.g., FIGS. 21, 28-31. The step of releaseably securing the package base 102 includes positioning the center of the package base 102 at the center of the X, Y, and Z axes of the tooling assembly 500 by fitting the package base 102 within a precision cut communication 520 of a template 510 of the tooling assembly 500 that is locked with pins 1210, 1212 to a common interface block 1200 and by resting the bottom surface 104 of the package base 102 on the top surface 420 of a baseplate 610 positioned between the template 510 and the carrier interface block 1200. The step of resting the package base 102 on the baseplate 610 positions the top surface 108 of the package base 102 on a plane that is substantially parallel to the plane of top surface 620 of the baseplate 610. The method includes the further steps of placing desired electronic devices in the package base 102 and then sealing the package base 102 with a lid 120 while the package base 102 is releaseably secured within the tooling assembly 500.

All of the aforementioned steps of aligning and using the tooling assemblies 300, 500 of the invention can be carried out manually or by automation.

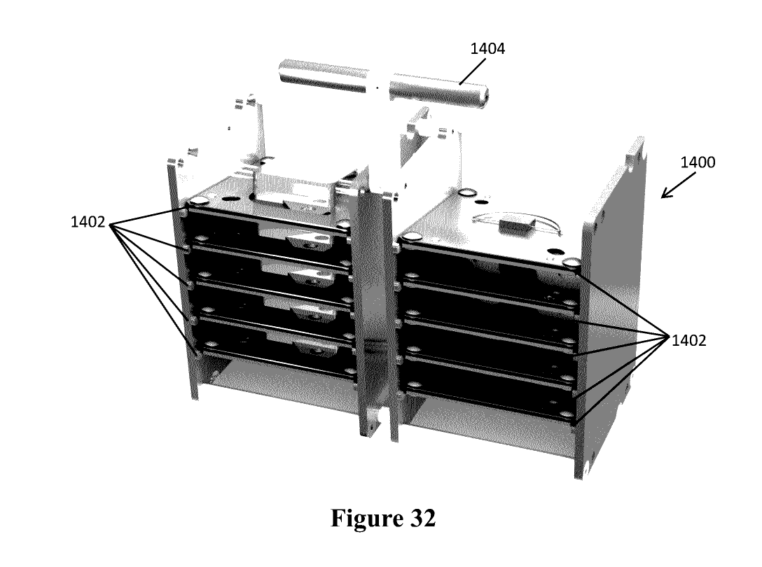

Referring now to FIG. 32, the invention also provides a cassette holder 1400 configured to be loaded with and to securely hold multiple tooling assemblies 300, 500. The cassette holder 1400 simply holds multiple tooling assemblies 300, 500 in a secure manner for transport. Instead of moving tooling assemblies 300, 500 one at a time, several can be loaded into a cassette holder 1400 and moved as a group. For example, multiple tooling assemblies 300, 500 can be loaded into multiple cassettes holders 1400 and placed into a single helium leak detector tank for simultaneous testing. One design feature of each cassette holder 1400 is that it can be stacked on another cassette holder 1400. This provides for a high packaging density for bulk processing, perhaps with a helium leak chamber as an example.

Several packages 100 can be placed in the cassette holder shown in FIG. 32 for transport and/or storage. The cassette holder 1400 comprises sets of corresponding, slightly declined (from front to rear) slots 1402 that are vertically spaced from one another at a height and width that permits clearance of tooling assemblies 300, 500 holding packages 100. The slots 1402 receive outside edges of fully assembled tooling assemblies 300, 500. The cassette holder 1400 can be closed on its bottom and external side and rear surfaces and open along its front and top surfaces. Other configurations can be used so long as the front of the cassette holder 1400 is accessible to slide tooling assemblies 300, 500 in and out of the slots 1402. The cassette holder 1400 includes a handle 1404, which may be fixed or pivot from a resting to an operable position. The handle 1404 can be used to transport the cassette holder 1400.

The cassettes carriers 1400 are standard and not unique to packages 100 or tooling assemblies 300, 500. Different package 100 types might be processed at the same time. In alternative embodiments, different size tooling assemblies 300, 500 can be used. For example, one assembly 300, 500 can be 50 mm square and the another assembly 300, 500 is 100 mm×50 mm. Each size corresponds with a unique cassette holder 1400 design.

Cassettes holders 1400 are reusable capital equipment purchases. The cassette holders 1400 can be machined and manufactured conventionally from 316 L stainless steel. As with the tooling assemblies 300, 500, the cassette holders 1400 are also designed with vacuum processing in mind. Therefore any design strives to minimize any entrapped gases. Mated surfaces are minimized. Fasteners are vented and use no blind threaded holes in accordance with good design practices for vacuum equipment in order to minimize virtual leaks.

While this subject matter has been disclosed with reference to specific embodiments, it is apparent that other embodiments and variations can be devised by others skilled in the art without departing from the true spirit and scope of the subject matter described herein. The appended claims include all such embodiments and equivalent variations.

What is claimed is:

1. An assembly for handling an electronic package comprising:
a template comprising a communication between a top surface and a bottom surface of the template, the communication having an internal peripheral surface that is shaped to correspond with and receive, in whole or in part, an external lateral portion of a base or walls of the electronic package, whereby the communication is configured to removeably secure and position the electronic package in a precise position relative to an assembly operation; and
a carrier plate comprising a top surface and a bottom surface, the carrier plate positioned beneath the template, whereby the top surface of the carrier plate and the bottom surface of the template are in contact or are positioned at a distance from one another;
whereby the fit of the template with the carrier plate is configured to secure the electronic package along at least the X axis and the Y axis of the carrier plate.

2. The assembly of claim 1 wherein said internal periphery of the communication has a tolerance of an external periphery of at least a portion of said base or walls of the electronic package.

3. The assembly of claim 2 wherein said tolerance comprises about 100 microns or less.

4. The assembly of claim 1 further comprising at least one spacer for positioning the template the distance from the carrier plate, wherein the distance is less than a height of the electronic package.

5. The assembly of claim 4 wherein the at least one spacer comprises a threaded connector that engages a first set of threads positioned through the template and a second set of threads positioned through the carrier plate.

6. The assembly of claim 1 further comprising an interface block having a center pin that extends vertically from a top surface of the interface block, the center pin extends through a first communication of the carrier plate and a first receiving hole of the template, whereby the carrier plate aligns with the template along a vertical axis of the center pin relative to the interface block.

7. The assembly of claim 6 further comprising a lateral pin that extends vertically from the top surface of the interface block, the lateral pin extends through a second communication of the carrier plate and a second receiving hole of the template, whereby the lateral pin engages the second communication and the second receiving hole to prevent rotation of the carrier plate and the template relative to the interface block.

8. The assembly of claim 7 wherein the center pin and the lateral pin lock the template in place relative to the X axis and the Y axis of the interface block.

9. The assembly of claim wherein the interface block, the carrier, and the template rest on one another.

10. The assembly of claim 9 wherein the template or the carrier comprise a plurality of dimples that position the template and the carrier at a distance from one another.

10. The assembly of claim 1 wherein the template comprises at least two subparts having reliefs configured to receive projections extending from the electronic package.

11. A method for controlling an electronic package during processing comprising:
positioning a tooling assembly relative to an operation of a manufacturing process, the tooling assembly comprises:
a template having a communication between a top surface and a bottom surface of the template, the communication having an internal periphery within a tolerance configured to hold and align a package base for the electronic package; and
a carrier plate having a top surface that is substantially parallel to the bottom surface of the template;
placing a package base in the communication of the template so that a bottom of the package base contacts the top surface of the carrier plate while a top surface of a seal ring of the electronic package extends above the top surface of said template, whereby said package base is supported in a precise position relative to an X axis and a Y axis of the carrier plate; and
aligning a lid on the top surface of the seal ring after electronics are placed within the package base, whereby sides of the lid are substantially equidistant from a top edge of the package base; and
sealing the lid to the package base with a sealing operation.

12. The method of claim 11 wherein the tooling assembly comprises a base having at least two projections that extend vertically from a top surface of the base, whereby the at least two projections fit within openings in a bottom surface of the carrier plate to align the tooling assembly relative to the sealing operation.

13. The method of claim 11 wherein the sealing operation comprises one or more of welding, soldering, or adhesion.

14. The method of claim 11 wherein the internal periphery of the template is configured to contact all or a portion of an external periphery of the package base.

15. The method of claim 11 wherein the template comprises a single plate or subparts having reliefs configured to receive projections extending from the package base.

16. The method of claim 11 wherein the template comprises at least one spacer for positioning the template at a distance from the carrier plate, wherein the distance is less than a height of the electronic package.

17. A tooling assembly for aligning a package base for hermetic sealing to a lid comprising:
a template having a cutout with an internal periphery that corresponds with at least a portion of an external periphery of a package base within a tolerance that is capable of receiving and holding the package base in a fixed position relative to an X axis and Y axis of the template;
a carrier plate positioned at a distance from the template that is less than a height of the package base; and
a base having at least two projections that extend vertically from a top surface of the base, whereby the at least two projections fit within openings in a bottom surface of the carrier plate to align the assembly relative to a sealing operation.

18. The tooling assembly of claim 17 wherein the template is configured to contact all or a portion of an external periphery of the package base.

19. The tooling assembly of claim 17 wherein the package base can be hermetically sealed with a lid to form an electronic package, a semiconductor package, or a microcircuit package.

20. The tooling assembly of claim 17 wherein the tolerance comprises about 50-250 microns.

21. The tooling assembly of claim 17 wherein the template comprises a single plate or subparts having reliefs configured to receive projections extending from the package base.
